(19) United States
(12) Patent Application Publication
(10) Pub. No.: US 2023/0366489 A1
(43) Pub. Date: Nov. 16, 2023

(54) DEVICE FOR GUIDING A LINE THROUGH A WALL IN A PRESSURE-TIGHT MANNER, AND METHOD FOR PRODUCING THE DEVICE

(71) Applicant: MICRO-EPSILON-MESSTECHNIK GMBH & CO. K.G., Ortenburg (DE)

(72) Inventors: Stefan Stelzl, Ortenburg (DE); Axel Seikowsky, Ortenburg (DE); Christian Ecke, Deggendorf (DE); Thomas Wisspeintner, Ortenburg (DE)

(21) Appl. No.: 18/245,284

(22) PCT Filed: Jul. 16, 2021
(86) PCT No.: PCT/DE2021/200096

§ 371 Date: Mar. 14, 2023

(30) Foreign Application Priority Data
Sep. 24, 2020 (DE) 10 2020 212 059.5
Oct. 6, 2020 (DE) 10 2020 212 608.9

(51) Int. Cl. F16L 5/10

(52) U.S. Cl. CPC F16L 5/10

(57) ABSTRACT

The invention relates to a device for the pressure-tight feedthrough of a line comprising a deformable jacket through a feedthrough in a wall which separates a first pressure area from a second pressure area with a sleeve surrounding the line in the area of the feedthrough, which has at least two spaced annular constrictions, notches, grooves or the like created by forming, between which the material of the jacket is compressed by forming into an integral ring seal acting between the jacket and the sleeve, where the sleeve is being pressure-tightly connected or being connectable to the wall around the feedthrough, at least from one side. Furthermore, the invention relates to a method for the manufacture of a corresponding device.

### CROSS REFERENCE TO RELATED APPLICATIONS

This application is a National Stage Application, filed under 35 U.S.C. § 371, of International Application No. PCT/DE2021/200096, filed Jul. 16, 2021, which international application claims priority to and the benefit of German Application No. 10 2020 212 059.5, filed Sep. 24, 2020, and German Application No. 10 2020 212 608.9, filed Oct. 6, 2020; the contents of all of which as are hereby incorporated by reference in their entireties.

### BACKGROUND

### Technical Field

The invention relates to a device for feeding a line comprising a deformable casing through a feedthrough in a wall in a pressure-tight manner, where the wall separates a first pressure area from a second pressure area. The pressure areas may have different pressures, for example, atmospheric pressure on one side and negative or positive pressure on the other side. In addition, high temperatures or very different temperatures may prevail on both sides.

At this point, it is noted that the term “wall” is to be understood broadly. This can be a wall between two rooms or a wall as part of a housing. It is important that it is a feedthrough through a wall that separates different pressure areas from one another, with the feedthrough of the line being understood as a weak point for isolating the two areas.

### Description of Related Art

In industrial applications in measuring technology, there is often the requirement to operate various components of a measuring chain in different pressure ranges. For example, a sensor is often operated in a different ambient pressure area than the associated evaluation electronics. For this purpose, the control and signal lines between the sensor and the evaluation electronics must be routed from one pressure area to the other pressure area via a feedthrough.

To guide control lines, cables or the like from a pressure-free area to an area with pressure or vacuum, so-called pressure or vacuum feedthroughs are common or known from practice.

For vacuum feedthroughs, the line is generally separated and then fed through to the opposite side via bonded, encapsulated, or glass-enclosed pins.

The disadvantage of this type of implementation is the extensive manufacturing and assembly process. At the separation point, the ambient medium could also be forced into the line, e.g., between the inner conductor and the shield, or between the strands. With a rapid drop in pressure, the casing of the line could burst.

Pressure feedthroughs are generally designed in such a way that the entire line is fed through the opening with a cable gland with a steel conduit thread (PG screw connection), or the like, and then sealed with an O-ring or the like on the casing of the line and the opening through screwing. The disadvantage is their extensive and large-volume design. PG screw connections require a lot of installation space, are heavy, and consist of several parts.

The common solutions are disadvantageous in that they cannot be used at high pressures and at the same time at high or very low temperatures, since the mechanical expansion of the components at high temperatures reduces the necessary prestressing of the O-rings.

### BRIEF SUMMARY

This invention is therefore based on the object of designing and developing a device of the generic type in such a way that the aforementioned disadvantages are at least largely eliminated. The device should be suitable for both pressure and vacuum applications. In particular, the device may not be damaged in the feedthrough area, even over a longer period of time of use. In addition, the tightness must be guaranteed over a wide temperature range, for example, over a temperature range from about −20° C. to +200° C.

A corresponding method for producing such a device must also be specified.

The above object is achieved by the features of claim 1 in relation to the device according to the invention.

Based on that, it is a device for the pressure-tight feedthrough of a line comprising a deformable jacket through a feedthrough in a wall, which separates a first pressure area from a second pressure area. The device comprises a sleeve, which surrounds the line in the feedthrough area and which has at least two annular constrictions, notches, grooves or the like which are created by forming and are spaced apart from one another and between which the material of the jacket is compressed by the forming to compress an integral annular seal acting between the jacket and the sleeve, where the sleeve is connected or is connectable to the wall in a pressure-tight manner around the feedthrough, at least from one side.

According to the invention, it has been recognized that the solutions known from the prior art are complex and susceptible to faults/error in the design. According to the invention, a seal between the line and the sleeve is created in situ, namely by simulating the functional principle of a sealing ring, which is created from the jacket of the line by means of a circumferential constriction, notch, groove or the like in a metal sleeve, where adjacent notches compress the material of the jacket onto each other, creating a kind of integral sealing ring created through material elevation. Depending on how close together the constrictions are and how deep the constrictions are formed, a more or less raised “sealing ring” is created as an integral part of the jacket material.

The term “line” is to be understood in its broadest sense. This can be, for example, an electrical line. Also, the line may be an optical line, such as a fiber optic cable. It is also conceivable that the line is designed as a fluid line, for example, in the sense of a pneumatic or hydraulic line. It is essential for the cable that there is a plastically deformable sheath, which does not necessarily have to be elastic. Lines with a jacket made of PVC, PUR, FKM (FFKM), FPM (FFPM), PTFE, ductile metal, etc. are particularly suitable.

The sleeve through which the line is routed is preferably made of ductile metal, so that it can be shaped using a suitable tool that acts on the jacket material.

In principle, the material of the sleeve can be any malleable metal. In a particularly advantageous manner, the material of the sleeve is approximately matched to the material of the wall with regard to the coefficient of thermal expansion, so that no stress cracks occur during operation, in particular with temperature fluctuations, due to different coefficients of thermal expansion in the area of a possible connection.

To further promote the sealing, it is conceivable that at least one additional ring-shaped constriction is provided, so that a total of three constrictions are formed. This means that between the constrictions, two ring seals are formed by material displacement/compressing of the jacket material.

The constrictions can be arranged equidistant to each other and can be designed to be approximately the same size. It is also conceivable to provide a different spacing of the constrictions to each other and thus also of the ring seals to each other, as required. For this purpose, the sleeve intended for deformation can be designed for different lengths across the line.

Particularly, with inherently soft lines, for example, with coaxial cables, it is advantageous if a support sleeve is provided directly or indirectly under the jacket, which sleeve serves as an abutment when the sleeve is formed. The support sleeve can be inserted into the line under the casing.

The sleeve is basically to be understood as an independent component and can be connected to the wall as required. Advantageously, the sleeve is an integral part of the wall or of a housing enclosing the wall, ensuring no sealing problem between the sleeve and the wall. For example, the sleeve could be an integral part of a cylindrical sensor housing, which is machined in such a way that the sleeve in question is carved out at one end, for example, by turning, eroding, etc.

Alternatively, the sleeve can be bonded or welded to the wall from one side.

As part of another design, it is conceivable that the sleeve is an integral part of a flange, which can be connected to the wall and can be used on different walls. What is essential here is a sealing connection between a flange surface of the flange and a contact surface of the wall, whereby conventional O-rings or flat seals can be used for this purpose.

The wall with the feedthrough can be part of the housing of technical equipment, for example, an electrical device, which can be a measuring device, in particular, a sensor. In such a case, the device according to the invention is used to seal between the measuring side of a sensor and the connection accommodated in a housing, if applicable with electronics.

With regard to the method according to the invention, the underlying object is achieved by the features of independent claim 15. The method serves, in particular, to produce the device discussed above.

In a first method step, the line is pulled into a sleeve or the line is covered with a tight-fitting sleeve.

The material of the outer jacket is pressed in the radial direction. Due to the internal structure of the line, the material cannot deviate inwards, which means that it is partially pushed away axially from the constriction. If the internal structure of the cable is too flexible (e.g., coax or triax cables with a foamed dielectric), a support sleeve can be pushed between the jacket and the internal structure of the cable before forming.

The constriction is carried out with a suitable tool or device. It must be designed in a circumferential fashion so that the material of the casing is deformed over the entire circumference. Simple crimping is not sufficient here. A squeezing device, for example, a toggle-joint press with circulating pressing pieces that form circle segments to produce a circulating constriction when compressed, could be used. Particularly suitable is a roller converter, which creates the constriction by guiding a roller head around it.

In another step, a second constriction is introduced at a certain distance to the first constriction. The material of the outer jacket is also squeezed radially here and partially pushed away axially from the constriction. However, since the first constriction prevents the axial pushing away in this direction, the material of the outer casing is practically compressed between the two constrictions. This creates an area between the two constrictions, where the material of the jacket is thickened and compressed: A sealing area develops between the constrictions, which is modeled on a sealing ring, such as an O-ring. The two steps can also be performed simultaneously with a suitable device. If pressure is now applied to the replicated O-ring through the surrounding medium of the pressure side, it is further pressed and its sealing effect is favored.

The shape, depth, distance, and characteristic of the constrictions determine the shape of the replicated O-ring. In an advantageous embodiment, the constrictions are dimensioned in such a way that the region of the deformable sleeve between them has almost the shape of a circular arc. In this form, the resulting pressure forces are absorbed particularly well, analogously to the O-ring. This achieves a high degree of tightness when pressurized over a wide temperature range of, for example, −20° C. to +200° C., since the overpressure supports the sealing effect at any temperature. Due to the symmetrical design of the constrictions, the sealing effect is even made possible in two directions, which also allows use when the pressure changes.

For particularly high tightness requirements, two or more sealing areas can also be arranged one behind the other.

Another advantage is the simple and compact design of such a feedthrough. Without additional components, a sealing area is created from the existing jacket of the cable, which also withstands high pressures. The first pressure range can be normal ambient pressure, the second pressure range can be either a vacuum or an overpressure. The process is particularly suitable for high pressures. Any desired combination of first and second pressure area is conceivable.

The method can be applied not only to electrical lines, but also to optical lines (fiber optic cables), pneumatic or hydraulic lines if these lines are routed from a first pressure area to a second pressure area.

### BRIEF DESCRIPTION OF THE FIGURES

There are various ways to advantageously configure and further develop the teaching of the present invention. For this purpose, reference is hereby made on the one hand to the claims dependent on claim 1, and on the other hand to the following explanation of preferred embodiments of the invention with reference to the drawings. In connection with the explanation of the preferred exemplary embodiments of the invention based on the drawing, preferred configurations and developments of the teaching are also explained in general. In the drawing, the figures show

FIG. 1 in a schematic view, a device for carrying out a conduit comprising a deformable casing in a pressure-tight manner through a passage in a wall not shown in the figure, wherein the conduit is guided through a sleeve before forming the sleeve,

FIG. 2 in a schematic view the subject matter of FIG. 1 after the sleeve has been formed,

FIG. 3 in a schematic view of the device according to the invention using the example of a coaxial line with a retracted support sleeve,

FIG. 4 a schematic view of another design example of a device according to the invention, wherein the sleeve is part of a sensor housing,

FIG. 5 in a schematic view another design example of a device according to the invention, wherein the sleeve is part of a flange for direct connection to the wall, and

FIG. 6 a schematic perspective view of the subject matter from FIG. 5.

### DETAILED DESCRIPTION OF VARIOUS EMBODIMENTS

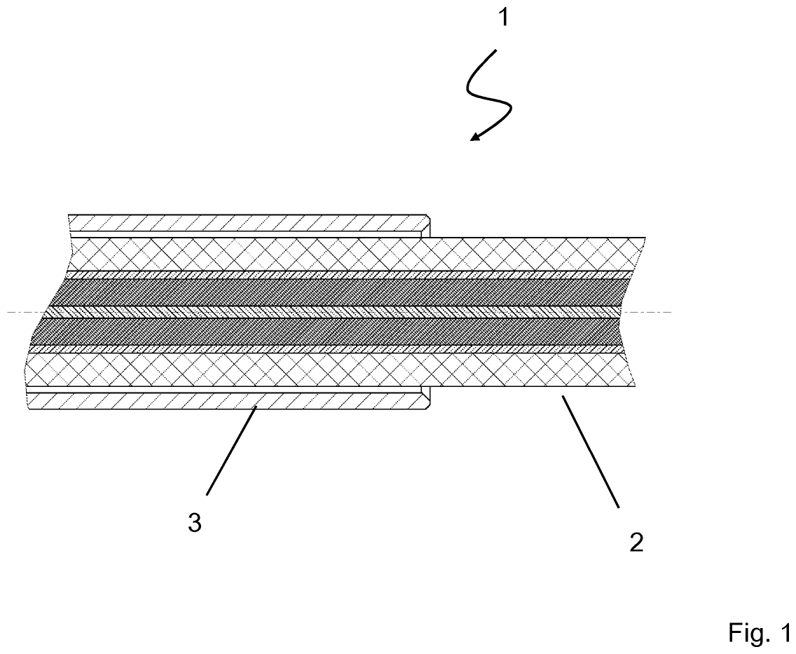

FIG. 1 shows the device 1 for leading through an electrical line 2, which is guided through a metal sleeve 3, before forming.

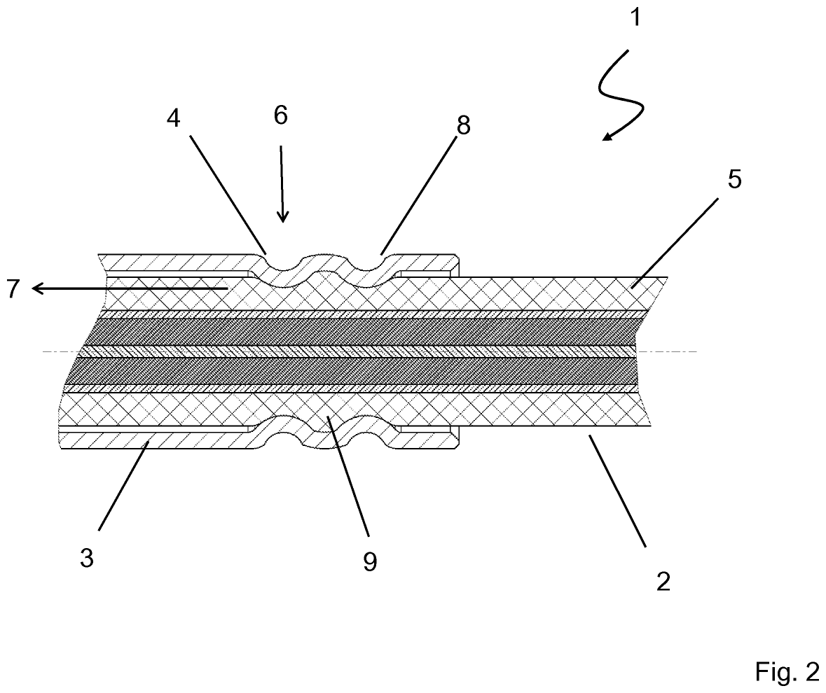

FIG. 2 shows the device 1 after forming. A first notch 4 compresses the jacket 5 in the radial direction 6, causing it to revert in the axial direction 7. The second notch 8 behind it also radially compresses the jacket, causing the jacket to also revert axially. In area 9 between the two notches, the jacket is pressed together and compressed, which forms a thickening. This thickening forms a sealing area 9 which is modeled after a sealing ring, for example an O-ring.

Here, the inner structure of the cable is stable enough to absorb the radial forces sufficiently, so that the material of the cable sheath reverts predominantly axially.

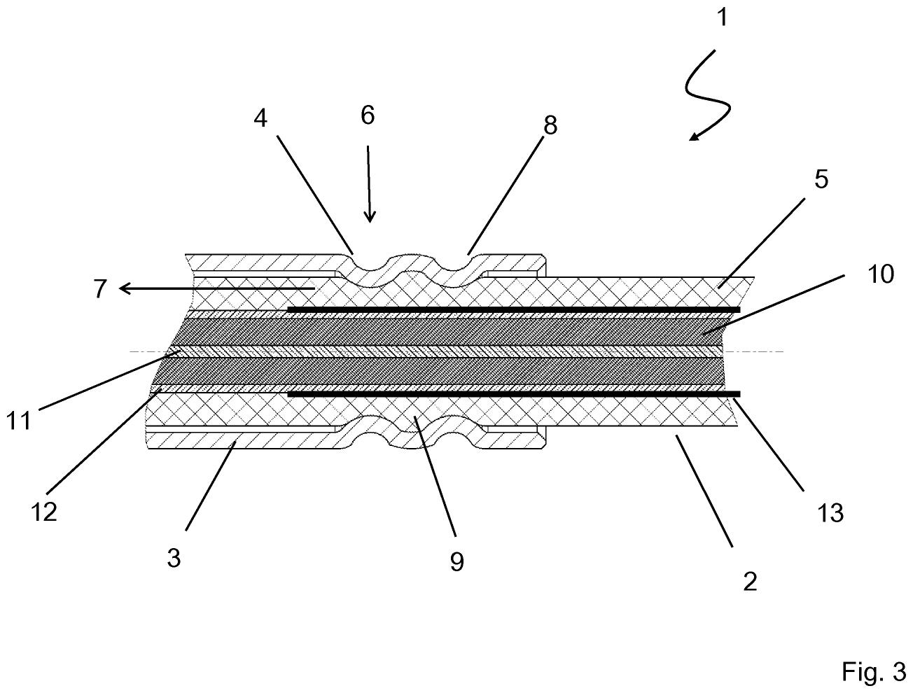

Using the example of a coaxial line 2, FIG. 3 shows a situation in which this is not the case. The coaxial line 2 consists of a dielectric 10 made of foamed material between the inner conductor 11 and the braided shield 12. The foamed dielectric 10 can at best absorb small forces, so that when the notches 4, 8 are formed, the dielectric 10 would be crushed, but the jacket 5 would not be deformed. To remedy this, a support sleeve 13 can be inserted between the jacket 5 and the inner structure, for example, above or below the screen mesh 12, which then absorbs the radial forces during forming.

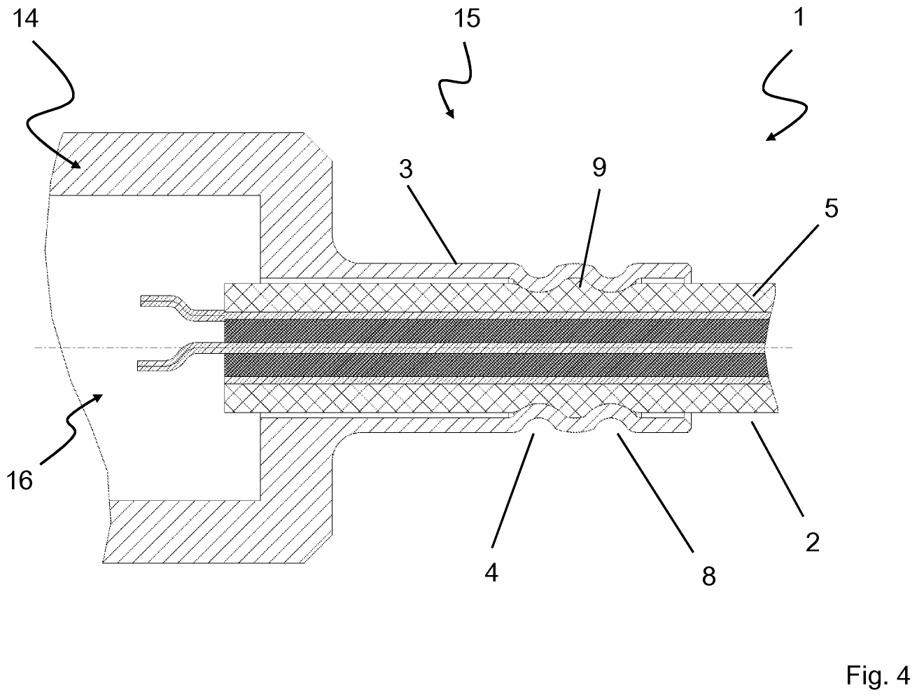

FIG. 4 shows the application of such an implementation 1 using the example of a sensor 14. The sensor 14 is located in a first range 15, which is subjected to high pressure and possibly high temperature. The sensor 14 itself is tight and resistant to pressure and temperature. Inside the sensor 14 there is normal pressure, which forms a second pressure area 16. To prevent the medium (e.g., air, or oil, water, etc.) in the first area 15 from penetrating along the line 2 between the jacket and the sleeve 3 into the sensor 14 and destroying it, the feedthrough 1 is sealed in accordance with the teaching of the invention. With two notches 4, 8, a sealing area 9 is modeled on an O-ring, which reliably prevents the medium from penetrating into the second pressure area 16, i.e., into the interior of the sensor 14.

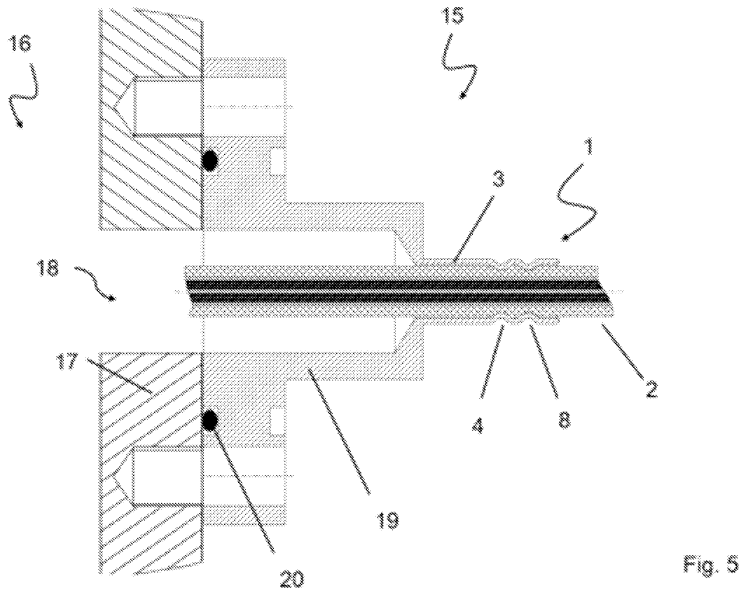

FIG. 5 shows the use of such a feedthrough 1 through a wall 17 between a first pressure area and a second pressure area 16. At an opening 18 in the wall 17, a pressure flange 19 is screwed and sealed with an O-ring 20 in a known manner. The line 2 extends through the feedthrough 1 in the pressure flange 19. A metal sleeve 3 is attached to the pressure flange 19 and forms the seal according to the invention by means of two notches 4, 8.

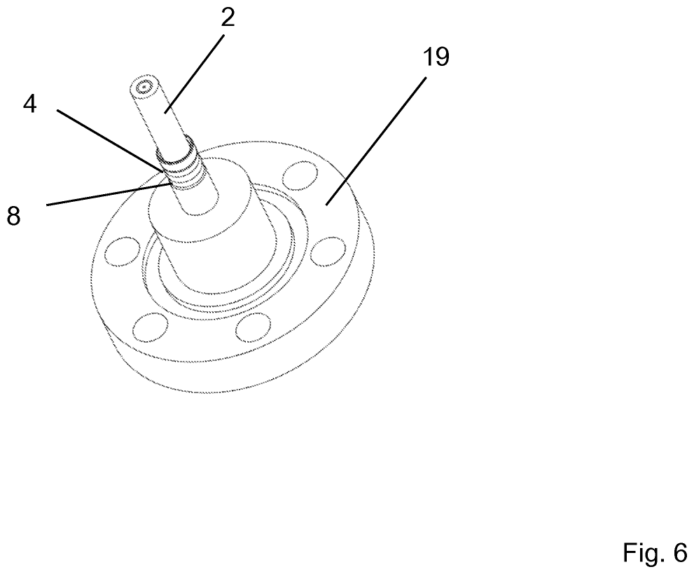

FIG. 6 shows the pressure flange 19 in a perspective oblique view with the line 2 and the notches 4, 8.

The design examples discussed above all relate to the feedthrough of electrical lines. Instead of the electrical lines, any lines, in particular, optical lines, hydraulic lines, or pneumatic lines, can be fed through. It is essential that the line comprises a deformable jacket, so that an integral ring seal can be generated for forming.

With respect to further advantageous configurations of the teaching according to the invention, it has been recognized that the solutions known from the prior art are complex and susceptible to faults/error in the design. According to the invention, a seal between the line and the sleeve is created in situ, namely by simulating the functional principle of a sealing ring, which is created from the jacket of the line by means of a circumferential constriction, notch, groove or the like in a metal sleeve, where adjacent notches compress the material of the jacket onto each other, creating a kind of integral sealing ring created through material elevation. Depending on how close together the constrictions are and how deep the constrictions are formed, a more or less raised “sealing ring” is created as an integral part of the jacket material.

The sleeve through which the line is routed is preferably made of ductile metal, so that it can be shaped using a suitable tool that acts on the jacket material. In principle, though, the material of the sleeve can be any malleable metal. In a particularly advantageous manner, the material of the sleeve is approximately matched to the material of the wall with regard to the coefficient of thermal expansion, so that no stress cracks occur during operation, in particular with temperature fluctuations, due to different coefficients of thermal expansion in the area of a possible connection.

To further promote the sealing, it is conceivable that at least one additional ring-shaped constriction is provided, so that a total of three constrictions are formed. This means that between the constrictions, two ring seals are formed by material displacement/compressing of the jacket material.

The constrictions can be arranged equidistant to each other and can be designed to be approximately the same size. It is also conceivable to provide a different spacing of the constrictions to each other and thus also of the ring seals to each other, as required. For this purpose, the sleeve intended for deformation can be designed for different lengths across the line. Particularly, with inherently soft lines, for example, with coaxial cables, it is advantageous if a support sleeve is provided directly or indirectly under the jacket, which sleeve serves as an abutment when the sleeve is formed. The support sleeve can be inserted into the line under the casing.

The sleeve is basically to be understood as an independent component and can be connected to the wall as required. Advantageously, the sleeve is an integral part of the wall or of a housing enclosing the wall, ensuring no sealing problem between the sleeve and the wall. For example, the sleeve could be an integral part of a cylindrical sensor housing, which is machined in such a way that the sleeve in question is carved out at one end, for example, by turning, eroding, etc. Alternatively, the sleeve can be bonded or welded to the wall from one side.

As part of another design, it is conceivable that the sleeve is an integral part of a flange, which can be connected to the wall and can be used on different walls. What is essential here is a sealing connection between a flange surface of the flange and a contact surface of the wall, whereby conventional O-rings or flat seals can be used for this purpose. The wall with the feedthrough can be part of the housing of technical equipment, for example, an electrical device, which can be a measuring device, in particular, a sensor. In such a case, the device according to the invention is used to seal between the measuring side of a sensor and the connection accommodated in a housing, if applicable with electronics.

With regard to the method according to the invention, in a first method step, the line is pulled into a sleeve or the line is covered with a tight-fitting sleeve. The material of the outer jacket is pressed in the radial direction. Due to the internal structure of the line, the material cannot deviate inwards, which means that it is partially pushed away axially from the constriction. If the internal structure of the cable is too flexible (e.g., coax or triax cables with a foamed dielectric), a support sleeve can be pushed between the jacket and the internal structure of the cable before forming.

The constriction is carried out with a suitable tool or device. It must be designed in a circumferential fashion so that the material of the casing is deformed over the entire circumference. Simple crimping is not sufficient here. A squeezing device, for example, a toggle-joint press with circulating pressing pieces that form circle segments to produce a circulating constriction when compressed, could be used. Particularly suitable is a roller converter, which creates the constriction by guiding a roller head around it.

In another step, a second constriction is introduced at a certain distance to the first constriction. The material of the outer jacket is also squeezed radially here and partially pushed away axially from the constriction. However, since the first constriction prevents the axial pushing away in this direction, the material of the outer casing is practically compressed between the two constrictions. This creates an area between the two constrictions, where the material of the jacket is thickened and compressed: A sealing area develops between the constrictions, which is modeled on a sealing ring, such as an O-ring. The two steps can also be performed simultaneously with a suitable device. If pressure is now applied to the replicated O-ring through the surrounding medium of the pressure side, it is further pressed and its sealing effect is favored.

The shape, depth, distance, and characteristic of the constrictions determine the shape of the replicated O-ring. In an advantageous embodiment, the constrictions are dimensioned in such a way that the region of the deformable sleeve between them has almost the shape of a circular arc. In this form, the resulting pressure forces are absorbed particularly well, analogously to the O-ring. This achieves a high degree of tightness when pressurized over a wide temperature range of, for example, −20° C. to +200° C., since the overpressure supports the sealing effect at any temperature. Due to the symmetrical design of the constrictions, the sealing effect is even made possible in two directions, which also allows use when the pressure changes. For particularly high tightness requirements, two or more sealing areas can also be arranged one behind the other.

Another advantage is the simple and compact design of such a feedthrough. Without additional components, a sealing area is created from the existing jacket of the cable, which also withstands high pressures. The first pressure range can be normal ambient pressure, the second pressure range can be either a vacuum or an overpressure. The process is particularly suitable for high pressures. Any desired combination of first and second pressure area is conceivable. The method can be applied not only to electrical lines, but also to optical lines (fiber optic cables), pneumatic or hydraulic lines if these lines are routed from a first pressure area to a second pressure area.

Lastly, it must expressly be noted that the above described design examples of the teaching according to the invention serve only to explain the claimed teaching, but do not limit said teaching to these design examples.

1. Device for the pressure-tight passage of a line comprising a deformable jacket through a feedthrough in a wall which separates a first pressure area from a second pressure area,
with a sleeve surrounding the line in the area of the feedthrough, which has at least two spaced annular constrictions, notches, grooves or the like created by forming, between which the material of the jacket is compressed by forming into an integral ring seal acting between the jacket and the sleeve, where the sleeve is being pressure-tightly connected or being connectable to the wall around the feedthrough, at least from one side.

2. The device according to claim 1, wherein the line is an electrical line.

3. The device according to claim 1, wherein the line is an optical line.

4. The device according to claim 1, wherein the line is a fluid line.

5. The device according to claim 1, wherein the casing consists of plastic or metal.

6. The device according to claim 1, wherein the sleeve is made of a ductile metal.

7. The device according to claim 1, wherein the material of the sleeve is approximately matched to the material of the wall with regard to the coefficient of thermal expansion.

8. The device according to claim 1, wherein at least another annular constriction is provided, so that two ring seals are formed between the constrictions.

9. The device according to claim 1, wherein the constrictions are arranged equidistantly from one another and are approximately the same size.

10. The device according to claim 1, wherein a support sleeve is provided directly or indirectly under the casing, which sleeve serves as an abutment when the sleeve is formed.

11. The device according to claim 1, wherein the sleeve is an integral part of the wall or of a housing surrounding the wall.

12. The device according to claim 1, wherein the sleeve is bonded or welded to the wall at least from one side.

13. The device according to claim 1, wherein the sleeve is an integral part of a flange which can be connected to the wall.

14. The device according to claim 1, wherein the wall is part of the housing of an electrical device.

15. Method for producing a device for the pressure-tight feedthrough of a line comprising a deformable jacket through a feedthrough in a wall which separates a first pressure area from a second pressure area, in particular, for the production of a device according to claim 1, wherein for producing the pressure-tight feedthrough the line or its jacket is drawn into a tight-fitting sleeve in the area of the feedthrough or covered with a tight-fitting sleeve and the sleeve is provided with at least two spaced-apart annular constrictions, notches, grooves or the like, whereby the jacket between the notches forms an annular seal that extends between the jacket and the sleeve and acts there as a seal.

16. Method according to claim 15, wherein a support sleeve is formed directly or indirectly under the casing, prior to the formation of the constrictions.

17. Method according to claim 15, wherein the constrictions are created through roll or rolling technology or via a toggle press.

18. The device of claim 3, wherein the line is a fiber optic cable.

19. The device of claim 4, wherein the line is a pneumatic or hydraulic line.

20. The device of claim 14, wherein the electrical device is a measuring device or a sensor.
